(19) United States
(12) Patent Application Publication
(10) Pub. No.: US 2024/0145264 A1
(43) Pub. Date: May 2, 2024

(54) APPARATUS FOR PROCESSING A SUBSTRATE

(71) Applicant: SEMES CO., LTD., Cheonan-si (KR)

(72) Inventors: Sungho KIM, Cheonan-si (KR); Jungsoo LEE, Cheonan-si (KR); Hyekyoung KIM, Seoul (KR)

(73) Assignee: SEMES CO., LTD., Cheonan-si (KR)

(21) Appl. No.: 18/496,224

(22) Filed: Oct. 27, 2023

(30) Foreign Application Priority Data
Oct. 31, 2022 (KR) 10-2022-0142598

(51) Int. Cl. H01L 21/67

(52) U.S. Cl. CPC H01L 21/67034; H01L 21/67017

(57) ABSTRACT

An apparatus for processing a substrate may include a drying chamber configured to dry at least two divided substrates from an original substrate, the drying chamber may have a drying space where the at least two divided substrates disposed therein. The apparatus for processing a substrate may include a dryness compensation part configured to compensate a difference of drynesses of chemical liquids coated on the at least two divided substrates such that the chemical liquids coated on the at least two divided substrates has a substantially same dryness.

### CROSS-REFERENCE TO RELATED APPLICATION

This application claims priority to Korean Patent Application No. 10-2022-0142598 filed on Oct. 31, 2022 in the Korean Intellectual Property Office (KIPO), the contents of which are herein incorporated by reference in its entirety.

### BACKGROUND

### 1. Field

Example embodiments of the invention relate to an apparatus for processing a substrate. More particularly, example embodiments of the invention relate to an apparatus for processing a substrate capable of drying chemical liquids coated on at least two divided substrates from an original substrate.

### 2. Related Technology

A conventional display device may be formed through manufacturing processes performed on a substrate having a relatively large size. For example, the manufacturing processes may include a coating process of providing a chemical liquid onto the substrate, a drying process of drying the chemical liquid coated on the substrate, etc.

Since the coating process and the drying process may not be properly performed on the substrate having the relatively large size, the coating process and the drying process may be performed on more than two divided substrates after dividing the substrate having the relatively large size into the more than two divided substrates.

However, the difference of drynesses of the chemical liquids coated on the divided substrates may be caused in the drying process because the chemical liquids may be sequentially coated on the divided substrates. Such a difference of drynesses of the chemical liquids may cause the failures of the manufacturing processes.

### SUMMARY

Aspects of the invention relate to an apparatus for processing a substrate capable of compensating a difference of drynesses of chemical liquids coated on at least two divided substrates from an original.

According to one aspect of the invention, there is provided an apparatus for processing a substrate. The apparatus for processing a substrate may include a drying chamber configured to dry at least two divided substrates from an original substrate, the drying chamber having a drying space where the at least two divided substrates disposed therein, and a dryness compensation part configured to compensate a difference of drynesses of chemical liquids coated on the at least two divided substrates such that the chemical liquids coated on the at least two divided substrates has a substantially same dryness.

In example embodiments, the dryness compensation part may adjust amounts of gases provided onto the chemical liquids coated on the at least two divided substrates to compensate the difference of drynesses of the chemical liquids coated on the at least two divided substrates.

In example embodiments, the at least two divided substrates may include a first divided substrate and a second divided substrate, and the apparatus for processing a substrate may include a first gas supply member for providing the gas onto the chemical liquid coated on the first divided substrate and a second gas supply member for providing the gas onto the chemical liquid coated on the second divided substrate.

In example embodiments, when the chemical liquid is coated on the second divided substrate after the chemical liquid is coated on the first divided substrate, an amount of the gas provided onto the chemical liquid coated on the first divided substrate may be substantially greater than an amount of the gas provided onto the chemical liquid coated on the second divided substrate.

In some example embodiments, the at least two divided substrates may include a first divided substrate and a second divided substrate, and the apparatus for processing a substrate may include a first supporting member for supporting the first divided substrates and a second supporting member for supporting the second divided substrates.

In some example embodiments, the dryness compensation part may adjust a distance between the first divided substrate and the first supporting member and a distance between the second divided substrate and the second supporting member to compensate the difference of drynesses of the chemical liquids coated on the first and the second divided substrates.

In some example embodiments, when the chemical liquid is coated on the second divided substrate after the chemical liquid is coated on the first divided substrate the distance between the first divided substrate and the first supporting member may be substantially smaller than the distance between the second divided substrate and the second supporting member.

In some example embodiments, the dryness compensation part may move the first supporting member in an upward direction or a downward direction, or may move the second supporting member in an upward direction or a downward direction.

In other example embodiments, the apparatus for processing a substrate may include a plurality of pins passing through the first and the second supporting members, and the dryness compensation part may move the plurality of pins in an upward direction or a downward direction.

According to another aspect of the invention, there is provided an apparatus for processing a substrate. The apparatus for processing a substrate may include a drying chamber configured to dry chemical liquids coated on at least two divided substrates from an original substrate; a supporting part configured to support the at least two divided substrates in the drying chamber; a gas supply member configured to provide gases onto the chemical liquids coated on the divided substrates disposed on the supporting part; and a dryness compensation part configured to compensate a difference of drynesses of chemical liquids coated on the at least two divided substrates such that the chemical liquids coated on the at least two divided substrates has a substantially same dryness.

In example embodiments, the at least two divided substrates may include a first divided substrate and a second divided substrate, the supporting part may include a first supporting member for supporting the first divided substrate and a second supporting member for supporting the second divided substrate, and the dryness compensation part may adjust a distance between the first divided substrate and the first supporting member and a distance between the second divided substrate and the second supporting member.

In example embodiments, when the chemical liquid is coated on the second divided substrate after the chemical liquid is coated on the first divided substrate the distance between the first divided substrate and the first supporting member may be substantially smaller than the distance between the second divided substrate and the second supporting member.

In some example embodiments, the at least two divided substrates may include a first divided substrate and a second divided substrate, the gas supply part may include a first gas supply member for providing the gas onto the chemical liquid coated on the first divided substrate and a second gas supply member for providing the gas onto the chemical liquid coated on the second divided substrate, and the dryness compensation part may adjust an amount of the gas provided onto the chemical liquid coated on the first divided substrate from the first gas supply member or an amount of the gas provided onto the chemical liquid coated on the second divided substrate from the second gas supply member.

In some example embodiments, when the chemical liquid is coated on the second divided substrate after the chemical liquid is coated on the first divided substrate, the amount of the gas provided onto the chemical liquid coated on the first divided substrate may be substantially greater than the amount of the gas provided onto the chemical liquid coated on the second divided substrate.

According to still another aspect of the invention, there is provided an apparatus for processing a substrate. The apparatus for processing a substrate may include a drying chamber configured to dry a chemical liquid coated a first divided substrate and a chemical liquid coated on a second divided substrate from an original substrate; a supporting part including a first supporting member for supporting the first divided substrate and a second supporting member for supporting the second divided substrate; a gas supply member including a first gas supply member for providing a gas onto the chemical liquid coated on the first divided substrate and a second gas supply member for providing the gas onto the chemical liquid coated on the first divided substrate; and a dryness compensation part configured to compensate a difference in a dryness of the chemical liquid coated on the first divided substrate and a dryness of the chemical liquid coated on the second divided substrate.

In example embodiments, the dryness compensation part may adjust a distance between the first divided substrate and the first supporting member and a distance between the second divided substrate and the second supporting member by moving the first supporting member in an upward direction or a downward direction, or by moving the second supporting member in an upward direction or a downward direction.

In example embodiments, when the chemical liquid is coated on the second divided substrate after the chemical liquid is coated on the first divided substrate the distance between the first divided substrate and the first supporting member may be substantially smaller than the distance between the second divided substrate and the second supporting member.

In other example embodiments, the supporting part may include a plurality of pins passing through the first and the second supporting members, and the dryness compensation part may adjust a distance between the first divided substrate and the first supporting member and a distance between the second divided substrate and the second supporting member by moving the plurality of pins in an upward direction or a downward direction

In some example embodiments, the dryness compensation part may adjust an amount of the gas provided onto the chemical liquid coated on the first divided substrate from the first gas supply member or an amount of the gas provided onto the chemical liquid coated on the second divided substrate from the second gas supply member.

In some example embodiments, when the chemical liquid is coated on the second divided substrate after the chemical liquid is coated on the first divided substrate, the amount of the gas provided onto the chemical liquid coated on the first divided substrate may be substantially greater than the amount of the gas provided onto the chemical liquid coated on the second divided substrate.

According to example embodiments, the difference of drynesses of the chemical liquids coated on the divided substrates may be compensated using the dryness compensation part even though the chemical liquids sequentially coated on the divided substrates such that desired layers or predetermined patterns may be uniformly formed on the divided substrates. Therefore, the failures of processes of manufacturing a display device such as an organic light emitting display (OLED) device. Further, the reliability and productivity of the display device may be improved using the apparatus for processing a substrate including the supporting part, the gas supply part and the dryness compensation part.

### BRIEF DESCRIPTION OF THE DRAWINGS

Example embodiments will be more clearly understood from the following detailed description taken in conjunction with the accompanying drawing. The following figures represent non-limiting, example embodiments as described herein.

FIG. 1 is a schematic cross-sectional view illustrating an apparatus for processing a substrate in accordance with example embodiments of the invention.

FIGS. 2 to 4 are schematic cross-sectional views illustrating the operations of components of the apparatus for processing a substrate in accordance with example embodiments of the invention.

### DESCRIPTION OF EMBODIMENTS

Various embodiments will be described more fully hereinafter with reference to the accompanying drawings, in which some embodiments are shown. The invention may, however, be embodied in many different forms and should not be construed as limited to the embodiments set forth herein. Rather, these embodiments are provided so that this description will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (for example, rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include a plurality of forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the face through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, it will be described an apparatus for processing a substrate according to example embodiments with reference to the accompanying drawings.

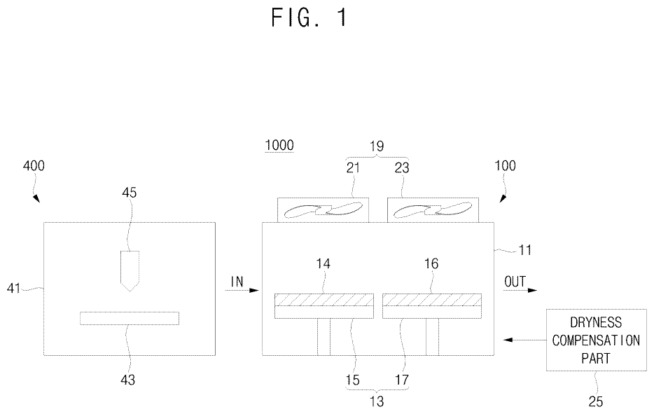

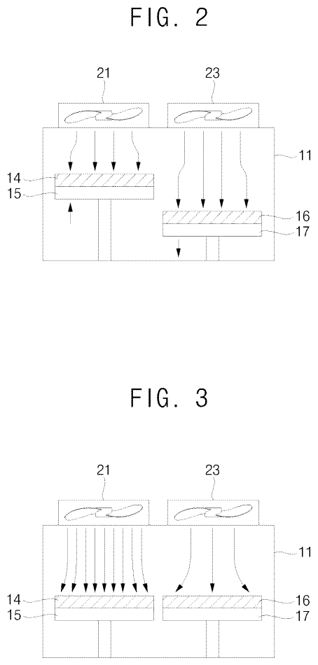

FIG. 1 is a schematic cross-sectional view illustrating an apparatus for processing a substrate in accordance with example embodiments of the invention. FIGS. 2 to 4 are schematic cross-sectional views illustrating the operations of components of the apparatus for processing a substrate in accordance with example embodiments of the invention.

Referring to FIG. 1 to FIG. 4, the apparatus for processing a substrate 1000 according to example embodiments may be employed in a process of drying a chemical liquid coated on a substrate. For example, the apparatus for processing a substrate 1000 may include a drying device 100 for drying a chemical liquid coated on a substrate.

In example embodiments, the apparatus for processing a substrate 1000 may dry chemical liquids coated on at least two substrates (hereinafter, referred to as “divided substrates”) divided from an original substrate. For example, the apparatus for processing a substrate 1000 may simultaneously dry chemical liquids coated two divided substrates.

The apparatus for processing a substrate 1000 may include a chemical liquid supply device 400 for providing the chemical liquids onto the divided substrates. In example embodiments, the chemical liquid supply device 400 may be used in processes of forming desired layers or predetermined patterns on the divided substrates for manufacturing a display device. The chemical liquid supply device 400 may include a coating chamber 41, nozzles 45, a stage 43, etc. The coating chamber 41 may provide a process space where the chemical liquids are provided onto the divided substrates. The nozzles 45 may supply the chemical liquids onto the divided substrates arranged in the process space. The stage 43 may support the divided substrates in the processes of providing the chemical liquids onto the divided substrates. Additionally, the stage 43 may transfer the divided substrates while floating the divided substrates over the stage 43 before and after the processes of providing the chemical liquids onto the divided substrates.

In example embodiments, the drying device 100 of the apparatus for processing a substrate 1000 may dry chemical liquids coated on a first divided substrates 14 and a second divided substrates 16. The drying device 100 may include a drying chamber 11, a supporting part 13, a gas supply part 19, a dryness compensation part 25, etc.

As illustrated in FIG. 1, the drying chamber 11 of the drying device 100 may provide a drying space in which the chemical liquids may be dried from the first divided substrate 14 and the second divided substrate 16. For example, the first divided substrate 14 may be loaded into the drying chamber 11, and then the second divided substrates 16 may be loaded into the drying chamber 11. In this case, the first divided substrate 14 may be disposed adjacent to an exit of the drying chamber 11 and the second divided substrates 16 may be placed adjacent to an entrance of the drying chamber 11.

The supporting part 13 may include a first supporting member 15 and a second supporting member 17 for supporting the first divided substrate 14 and the second divided substrate 16, respectively. Here, the first supporting member 15 may be disposed adjacent to the exit of the drying chamber 11 and the second supporting member 17 may be disposed adjacent to the entrance of the drying chamber 11.

In example embodiments, the first divided substrate 14 and the second divided substrate 16 may be arranged in parallel in the drying space. In other words, the first supporting member 15 and the second supporting member 17 may be disposed in parallel in the drying chamber 11. Here, the chemical liquid may be provided onto the first divided substrate 14 from the nozzles 45, and then the chemical liquid may be provided onto the second divided substrate 16 from the nozzles 45. That is, the chemical liquids may be sequentially supplied from the nozzles 45 onto the first and the second divided substrates 14 and 16. As a result, the difference between the dryness of the chemical liquid coated on the first divided substrate 14 and the dryness of the chemical liquid coated on the second divided substrate 16 may be caused while the chemical liquids coated on the first and the second divided substrates 14 and 16 are dried in the drying chamber 11, as described below.

As illustrated in FIG. 2, the supporting part 13 including the first and the second supporting members 15 and 17 may move in an upward direction and a downward direction in the drying chamber 11. For example, each of the first supporting member 15 and the second supporting member 17 may move along the upward and the downward directions in the drying space. In this case, the first supporting member 15 and the second supporting member 17 may simultaneously move in the drying chamber 11. Alternatively, the first supporting member 15 and the second supporting member 17 may sequentially move in the upward and the downward directions.

Further, the supporting part 13 may transfer the first and the second divided substrates 14 and 16 in the drying chamber 11. For example, each of the first supporting member 15 and the second supporting member 17 may include a transfer member such as a conveyor for transferring the first divided substrate 14 and the second divided substrate 16 from the entrance of the drying chamber 11 toward the exit of the drying chamber 11. In example embodiments, the transfer members of the first and the second supporting members 15 and 17 may simultaneously move in the upward and the downward directions on the drying chamber 11. In some example embodiments, the transfer members may sequentially or individually move along the upward and the downward directions.

In example embodiments, the supporting part 123 having the first and the second supporting members 15 and 17 may include cylinder members for the upward movements and downward movements of the first and the second supporting members 15 and 17. For example, the cylinder members may move the transfer members in the upward and the downward directions.

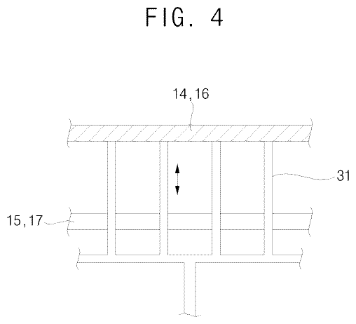

In some example embodiments, as illustrated in FIG. 4, the supporting part 13 may include a plurality of pins 31 for moving the first divided substrate 14 and the second divided substrate 16 in the upward and the downward directions. The plurality of pins 31 may pass through the first and the second divided substrates 15 and 17 and then make contact bottom faces of the first and the second divided substrates 14 and 16, respectively. For example, when the first and the second supporting members 15 and 17 include the transfer members such as the conveyers, the plurality of pins 31 may penetrate the conveyers and contact the bottom faces of the first and the second divided substrates 14 and 16, respectively.

In the apparatus for processing a substrate 100 including the above-described configuration, the chemical liquid may be coated on the second divided substrate 16 from the chemical liquid supply device 400, and then the second divided substrate 16 may be transferred into the drying chamber 11. In the drying chamber 11, the second divided substrate 16 may pass the first supporting member 15 and locate on the second supporting member 17. Further, the chemical liquid may be coated on the first divided substrate 14, and the first divided substrate 15 may be placed on the first supporting member 15. At this time, the second divided substrate 16 may wait on the second supporting member 17. In other words, the second divided substrate 16 may be still placed on the second supporting member 17 while the chemical liquid is coated on the first divided substrate 14 and the first divided substrate 14 may be transferred onto the first supporting member 15. Therefore, the second divided substrate 16 may stay relatively longer than the first divided substrate 14 in the drying chamber 11.

In example embodiments, the gas supply part 19 may provides gases onto the first divided substrate 14 and the second divided substrate 16 while a drying process is performed on the first divided substrate 14 and the second divided substrate 16. For example, the gas supply part 19 may provide air onto the first and the second divided substrates 14 and 16 for drying the chemical liquids coated on the first and the second divided substrates 14 and 16.

The gas supply part 19 may include a first gas supply member 21 and a second gas supply member 23. The first gas supply member 21 and the second gas supply member 23 may be disposed over the first supporting member 15 and the second supporting member 17, respectively. Thus, the first gas supply member 21 and the second gas supply member 23 may provide the gases onto the first divided substrate 14 and the second divided substrate 16. To this end, each of the first gas supply member 21 and the second gas supply member 23 may include a blowing member such as a fan. For example, each of the first gas supply member 21 and the second gas supply member 23 may include an EFU (equipment fan filter unit).

As described above, the second divided substrate 16 may stay for a time relatively longer than that of the first divided substrate 14 in the drying chamber 11. As a result, the difference between the dryness of the chemical liquid coated on the first divided substrate 14 and the dryness of the chemical liquid coated on the second divided substrate 16. For example, the dryness of the chemical liquid coated on the second divided substrate 16 may be substantially higher than that of the chemical liquid coated on the first divided substrate 14.

If the successive manufacturing processes are performed on the first and the second divided substrates 14 and 16 without compensating the difference between the drynesses of the chemical liquids coated on the first and the second divided substrates 14 and 16, stains may be generated on the desired layers or the predetermined patterns formed from the chemical liquids, or the difference of thicknesses between the layers and patterns. Such problems may cause the failures in the manufacturing processes and may reduce the productivity and reliability of the display device.

Considering the above-mentioned problems, the apparatus for processing a substrate 1000 may include the dryness compensation part 25 to substantially compensate the difference of the drynesses of the chemical liquids coated on the first and the second divided substrates 14 and 16. For example, the dryness compensation part 25 may adjust the amounts of evaporation of the chemical liquids coated on the first and the second divided substrates 14 and 16.

In example embodiments, to compensate the difference in the drynessses of the chemical liquids coated on the first and the second divided substrates 14 and 16, the dryness compensation part 25 may adjust the height of the first divided substrate 14 and/or the height of the second divided substrate 16. For example, the dryness compensation part 25 may move the first supporting member 15 having the first divided substrate 15 thereon in the upward direction and/or may move the second supporting member 17 having the second divided substrate 16 thereon along the downward direction. As a result, the dryness of the chemical liquid coated on the first divided substrate 14 may substantially identical to the dryness of the chemical liquid coated on the second divided substrate 16 since the dryness of the chemical liquid coated on the first divided substrate 14 may fast increase than the dryness of the chemical liquid coated on the second divided substrate 16.

In some example embodiments, the dryness compensation part 25 may control the amount of the gas provided from the first gas supply member 21 and/or the amount of the gas provided from the second gas supply member 23. For example, the dryness compensation part 25 may increase the amount of the gas supplied onto the chemical liquid coated on the first divided substrate 14 from the first gas supply member 21 and/or may decrease the amount of the gas supplied onto the chemical liquid coated on the second divided substrate 16 from the second gas supply member 23. Accordingly, the dryness of the chemical liquid coated on the first divided substrate 14 may substantially identical to the dryness of the chemical liquid coated on the second divided substrate 16 since the dryness of the chemical liquid coated on the first divided substrate 14 may fast increase than the dryness of the chemical liquid coated on the second divided substrate 16.

In other example embodiments, the dryness compensation part 25 may control the amount of the gas provided from the first gas supply member 21 and/or the amount of the gas provided from the second gas supply member 23 while adjusting the height of the first divided substrate 14 and/or the height of the second divided substrate 16. In this case, the dryness of the chemical liquid coated on the first divided substrate 14 may more rapidly increase than the dryness of the chemical liquid coated on the second divided substrate 16 such that the dryness of the chemical liquid coated on the first divided substrate 14 may more rapidly identical to the dryness of the chemical liquid coated on the second divided substrate 16.

According to example embodiments, as illustrated in FIG. 2, the dryness compensation part 25 may move the first supporting member 15 in the upward direction and/or may move the second supporting member 17 in the downward direction while the dryness compensation part 25 may maintain the amount of the gas provided from the first gas supply member 21 substantially equal to the amount of the gas provided from the second gas supply member 23, so that the first distance between the first divided substrate 14 and the first gas supply member 21 may be substantially smaller than the second distance between the second divided substrate 16 and the second supporting member 23. The amount of evaporation of the chemical liquid coated on the first divided substrate 14 may be substantially greater than the amount of evaporation of the chemical liquid coated on the second divided substrate 16 such that the dryness of the chemical liquid coated on the first divided substrate 14 may substantially identical to the dryness of the chemical liquid coated on the second divided substrate 16.

According to some example embodiments, as illustrated in FIG. 4, when the supporting member 13 includes the plurality of pins 31 passing through the first and the second supporting members 15 and 17, the dryness compensation part 25 may move the plurality of pins 31 in the upward direction and/or the downward direction such that the first distance between the first supporting member 21 and the first divided substrate 14 may be substantially shorter than the second distance between the second supporting member 23 and the second divided substrate 16. Therefore, the dryness of the chemical liquid coated on the first divided substrate 14 may substantially identical to the dryness of the chemical liquid coated on the second divided substrate 16 because amount of evaporation of the chemical liquid coated on the first divided substrate 14 may be substantially greater than the amount of evaporation of the chemical liquid coated on the second divided substrate 16.

According to other example embodiments, as illustrated in FIG. 3, the dryness compensation part 25 may control the first and the second gas supply members 21 and 23 while the dryness compensation part 25 may maintain the height of the first gas supply member 21 substantially equal to the height of the second gas supply member 23, so that the amount of the gas provided onto the first divided substrate 14 from the first gas supply member 21 may be substantially greater than the amount of the gas provided onto the second divided substrate 16 from the second gas supply member 23. As a result, he amount of evaporation of the chemical liquid coated on the first divided substrate 14 may be substantially greater than the amount of evaporation of the chemical liquid coated on the second divided substrate 16 such that the dryness of the chemical liquid coated on the first divided substrate 14 may substantially identical to the dryness of the chemical liquid coated on the second divided substrate 16.

As described above, the apparatus for processing a substrate 100 may uniformly form the desired layers or the predetermined patterns on the first and the second divided substrates 14 and 16 using the dryness compensation part 25, thereby preventing the failures in the manufacturing processes and improving the productivity and reliability of the display device.

Although the apparatus for processing a substrate 1000 may dry the chemical liquid s coated on the first and the second divided substrates 14 and 16 in the above example embodiments, the invention cannot be limited such a configuration. Specifically, the apparatus for processing a substrate 1000 may dry chemical liquids coated on a first divided substrate to an N (N is a positive integer) divided substrate. In this case, the apparatus for processing a substrate 1000 may include a first supporting member to an N supporting member, and also a first gas supply member to an N gas supply member.

In some example embodiments, the apparatus for processing a substrate 1000 may dry chemical liquids coated on at least two divided substrates as well as a chemical liquid coated on an original substrate.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the invention. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. An apparatus for processing a substrate comprising:
a drying chamber configured to dry at least two divided substrates from an original substrate, the drying chamber having a drying space where the at least two divided substrates disposed therein; and
a dryness compensation part configured to compensate a difference of drynesses of chemical liquids coated on the at least two divided substrates such that the chemical liquids coated on the at least two divided substrates has a substantially same dryness.

2. The apparatus for processing a substrate of claim 1, wherein the dryness compensation part adjust amounts of gases provided onto the chemical liquids coated on the at least two divided substrates to compensate the difference of drynesses of the chemical liquids coated on the at least two divided substrates.

3. The apparatus for processing a substrate of claim 2, wherein the at least two divided substrates include a first divided substrate and a second divided substrate, and wherein the apparatus for processing a substrate comprises a first gas supply member for providing the gas onto the chemical liquid coated on the first divided substrate and a second gas supply member for providing the gas onto the chemical liquid coated on the second divided substrate.

4. The apparatus for processing a substrate of claim 3, wherein when the chemical liquid is coated on the second divided substrate after the chemical liquid is coated on the first divided substrate, an amount of the gas provided onto the chemical liquid coated on the first divided substrate is substantially greater than an amount of the gas provided onto the chemical liquid coated on the second divided substrate.

5. The apparatus for processing a substrate of claim 2, wherein the at least two divided substrates include a first divided substrate and a second divided substrate, and wherein the apparatus for processing a substrate comprises a first supporting member for supporting the first divided substrates and a second supporting member for supporting the second divided substrates.

6. The apparatus for processing a substrate of claim 5, wherein the dryness compensation part adjusts a distance between the first divided substrate and the first supporting member and a distance between the second divided substrate and the second supporting member to compensate the difference of drynesses of the chemical liquids coated on the first and the second divided substrates.

7. The apparatus for processing a substrate of claim 6, wherein when the chemical liquid is coated on the second divided substrate after the chemical liquid is coated on the first divided substrate the distance between the first divided substrate and the first supporting member is substantially smaller than the distance between the second divided substrate and the second supporting member.

8. The apparatus for processing a substrate of claim 6, wherein the dryness compensation part moves the first supporting member in an upward direction or a downward direction, or moves the second supporting member in an upward direction or a downward direction.

9. The apparatus for processing a substrate of claim 6, wherein the apparatus for processing a substrate comprises a plurality of pins passing through the first and the second supporting members, and wherein the dryness compensation part moves the plurality of pins in an upward direction or a downward direction.

10. An apparatus for processing a substrate comprising:
a drying chamber configured to dry chemical liquids coated on at least two divided substrates from an original substrate;
a supporting part configured to support the at least two divided substrates in the drying chamber;
a gas supply member configured to provide gases onto the chemical liquids coated on the divided substrates disposed on the supporting part; and
a dryness compensation part configured to compensate a difference of drynesses of chemical liquids coated on the at least two divided substrates such that the chemical liquids coated on the at least two divided substrates has a substantially same dryness.

11. The apparatus for processing a substrate of claim 10, wherein the at least two divided substrates include a first divided substrate and a second divided substrate, wherein the supporting part includes a first supporting member for supporting the first divided substrate and a second supporting member for supporting the second divided substrate, and wherein the dryness compensation part adjusts a distance between the first divided substrate and the first supporting member and a distance between the second divided substrate and the second supporting member.

12. The apparatus for processing a substrate of claim 11, wherein when the chemical liquid is coated on the second divided substrate after the chemical liquid is coated on the first divided substrate the distance between the first divided substrate and the first supporting member is substantially smaller than the distance between the second divided substrate and the second supporting member.

13. The apparatus for processing a substrate of claim 10, wherein the at least two divided substrates include a first divided substrate and a second divided substrate, wherein the gas supply part includes a first gas supply member for providing the gas onto the chemical liquid coated on the first divided substrate and a second gas supply member for providing the gas onto the chemical liquid coated on the second divided substrate, and wherein the dryness compensation part adjusts an amount of the gas provided onto the chemical liquid coated on the first divided substrate from the first gas supply member or an amount of the gas provided onto the chemical liquid coated on the second divided substrate from the second gas supply member.

14. The apparatus for processing a substrate of claim 13, wherein when the chemical liquid is coated on the second divided substrate after the chemical liquid is coated on the first divided substrate, the amount of the gas provided onto the chemical liquid coated on the first divided substrate is substantially greater than the amount of the gas provided onto the chemical liquid coated on the second divided substrate.

15. An apparatus for processing a substrate comprising:
a drying chamber configured to dry a chemical liquid coated a first divided substrate and a chemical liquid coated on a second divided substrate from an original substrate;
a supporting part including a first supporting member for supporting the first divided substrate and a second supporting member for supporting the second divided substrate;
a gas supply member including a first gas supply member for providing a gas onto the chemical liquid coated on the first divided substrate and a second gas supply member for providing the gas onto the chemical liquid coated on the first divided substrate; and
a dryness compensation part configured to compensate a difference in a dryness of the chemical liquid coated on the first divided substrate and a dryness of the chemical liquid coated on the second divided substrate.

16. The apparatus for processing a substrate of claim 15, wherein the dryness compensation part adjusts a distance between the first divided substrate and the first supporting member and a distance between the second divided substrate and the second supporting member by moving the first supporting member in an upward direction or a downward direction, or by moving the second supporting member in an upward direction or a downward direction.

17. The apparatus for processing a substrate of claim 16, wherein when the chemical liquid is coated on the second divided substrate after the chemical liquid is coated on the first divided substrate the distance between the first divided substrate and the first supporting member is substantially smaller than the distance between the second divided substrate and the second supporting member.

18. The apparatus for processing a substrate of claim 15, wherein the supporting part includes a plurality of pins passing through the first and the second supporting members, and wherein the dryness compensation part adjusts a distance between the first divided substrate and the first supporting member and a distance between the second divided substrate and the second supporting member by moving the plurality of pins in an upward direction or a downward direction

19. The apparatus for processing a substrate of claim 15, wherein the dryness compensation part adjusts an amount of the gas provided onto the chemical liquid coated on the first divided substrate from the first gas supply member or an amount of the gas provided onto the chemical liquid coated on the second divided substrate from the second gas supply member.

20. The apparatus for processing a substrate of claim 19, wherein when the chemical liquid is coated on the second divided substrate after the chemical liquid is coated on the first divided substrate, the amount of the gas provided onto the chemical liquid coated on the first divided substrate is substantially greater than the amount of the gas provided onto the chemical liquid coated on the second divided substrate.
